(19) United States
(12) Patent Application Publication
(10) Pub. No.: US 2014/0284814 A1
(43) Pub. Date: Sep. 25, 2014

(54) SEMICONDUCTOR DEVICE AND MANUFACTURING METHOD THEREOF

(71) Applicant: KABUSHIKI KAISHA TOSHIBA, Tokyo (JP)

(72) Inventors: Tatsuro SAITO, Yokkaichi-shi (JP); Makoto WADA, Yokkaichi-shi (JP); Atsunobu ISOBAYASHI, Yokkaichi-shi (JP); Akihiro KAJITA, Yokkaichi-shi (JP)

(21) Appl. No.: 13/958,093

(22) Filed: Aug. 2, 2013

(30) Foreign Application Priority Data
Mar. 22, 2013 (JP) 2013-060653

(51) Int. Cl. H01L 23/48; H01L 21/768

(52) U.S. Cl. CPC H01L 23/481; H01L 21/76877; Y10S 977/742; Y10S 977/84; Y10S 977/94; B82Y 40/00
USPC 257/774; 438/667; 977/742; 977/840; 977/932

(57) ABSTRACT

According to one embodiment, a semiconductor device includes a first wiring, a second wiring disposed in the same layer as the first wiring, a first via connected to a bottom surface of the first wiring and formed of a carbon nanotube, and a second via connected to a bottom surface of the second wiring and formed of a metal.

### CROSS-REFERENCE TO RELATED APPLICATIONS

This application is based upon and claims the benefit of priority from Japanese Patent Application No. 2013-060653, filed Mar. 22, 2013, the entire contents of which are incorporated herein by reference.

### FIELD

Embodiments described herein relate generally to a semiconductor device using a carbon nanotube, and a method of manufacturing the same.

### BACKGROUND

There has been developed a semiconductor device using a carbon nanotube (CNT) which is expected as a low-resistance wiring material. In this semiconductor device, if a carbon nanotube is used as a contact, low-resistance wiring can be realized in long-distance wiring.

For example, when contacts with high aspect ratios of, e.g. a 3D device are to be formed, it is necessary to form contacts with various heights and diameters in the same layer. In this case, by using a carbon nanotube for a contact with a large height and a large diameter, reduction in resistance of a via can be expected. However, when a carbon nanotube is applied to a thin contact with a small height, it is difficult to lower the via resistance to a level that is equal to or less than the via resistance of a conventional metal material.

### BRIEF DESCRIPTION OF THE DRAWINGS

FIG. 1 is a cross-sectional view which schematically illustrates the structure of a semiconductor device according to an embodiment.

FIG. 2 is a graph showing the ballistic length dependency of a via resistance in the embodiment.

FIG. 3A and FIG. 3B are cross-sectional views illustrating a fabrication step of the semiconductor device of the embodiment.

FIG. 4A and FIG. 4B are cross-sectional views illustrating a fabrication step of the semiconductor device of the embodiment, following the steps in FIG. 3A and FIG. 3B.

FIG. 5A and FIG. 5B are cross-sectional views illustrating a fabrication step of the semiconductor device of the embodiment, following the steps in FIG. 4A and FIG. 4B.

FIG. 6A and FIG. 6B are cross-sectional views illustrating a fabrication step of the semiconductor device of the embodiment, following the steps in FIG. 5A and FIG. 5B.

FIG. 7A and FIG. 7B are cross-sectional views illustrating a fabrication step of the semiconductor device of the embodiment, following the steps in FIG. 6A and FIG. 6B.

FIG. 8A and FIG. 8B are cross-sectional views illustrating a fabrication step of the semiconductor device of the embodiment, following the steps in FIG. 7A and FIG. 7B.

FIG. 9A and FIG. 9B are cross-sectional views illustrating a fabrication step of the semiconductor device of the embodiment, following the steps in FIG. 8A and FIG. 8B.

FIG. 10A and FIG. 10B are cross-sectional views illustrating a fabrication step of the semiconductor device of the embodiment, following the steps in FIG. 9A and FIG. 9B.

FIG. 11A and FIG. 11B are cross-sectional views illustrating a fabrication step of the semiconductor device of the embodiment, following the steps in FIG. 10A and FIG. 10B.

### DETAILED DESCRIPTION

In general, according to one embodiment, a semiconductor device includes a first wiring, a second wiring disposed in the same layer as the first wiring, a first via connected to a bottom surface of the first wiring and formed of a carbon nanotube, and a second via connected to a bottom surface of the second wiring and formed of a metal.

An embodiment will now be described with reference to the accompanying drawings. In the description, common parts are denoted by like reference numerals throughout the drawings.

[1] Outline

In recent years, as a low-resistance material, a novel carbon material such as fullerence has been applied to wiring material. In particular, the application of a carbon nanotube (CNT) to a contact plug has been examined. The carbon nanotube is such a carbon material that graphene which is a multilayer carbon material of a film, in which benzene rings are regularly arranged in a plane, is formed in a cylindrical structure with a diameter of 10 to 100 nm. The graphene is a very thin carbon material in which about one to 100 films, in each of which benzene rings are regularly arranged in a plane, are stacked.

It is expected that the carbon nanotube, by virtue of its quantized conduction characteristics, is used as low-resistance wiring for an LSI, in place of metal wiring. In particular, since the ballistic length is very great (about 100 nm to 1 μm), the carbon nanotube is more advantageous for electric conduction of long-distance wiring. Furthermore, since the structure of the carbon nanotube is cylindrical and a film of the carbon nanotube can be vertically formed by CVD (Chemical Vapor Deposition), the carbon nanotube has excellent matching with a vertical wiring formation process. As described above, the carbon nanotube is the material having excellent electrical characteristics as vertical wiring, and, in particular, it is possible that low-resistance wiring is realized in long-distance wiring.

On the other hand, when the carbon nanotube is used for such a contact with a small length and a small diameter as used for ordinary fine wiring connection, the number of carbon nanotubes, which can be formed, is limited, and the ballistic length of the carbon nanotube cannot advantageously be used. Thus, in order to realize a resistance which is equal to the resistance of a metal via, further reduction in resistance is required.

In particular, among 3D devices which require a connection by a long-distance contact, there are many devices which require a fine low-resistance contact in the same layer as a long-distance contact. In this case, it is important to realize, in the same layer, reduction in resistance of the long-distance contact and reduction in resistance of the fine contact.

This being the case, in the present embodiment, in a semiconductor device such as a 3D device in which contact vias with a plurality of heights and diameters are present in the same layer, a carbon nanotube via is used for a long-distance contact and a metal via is used for a fine contact. Thereby, a structure, in which the carbon nanotube via and the metal via are mixedly present in the same layer, is proposed.

In the present embodiment, the “via” refers to both a member which connects different metal wiring layers and a member which connects an element, such as a transistor, and a metal wiring layer. The “via” in this embodiment, however, also includes a contact which connects an element, such as a transistor, and a metal wiring.

[2] Structure

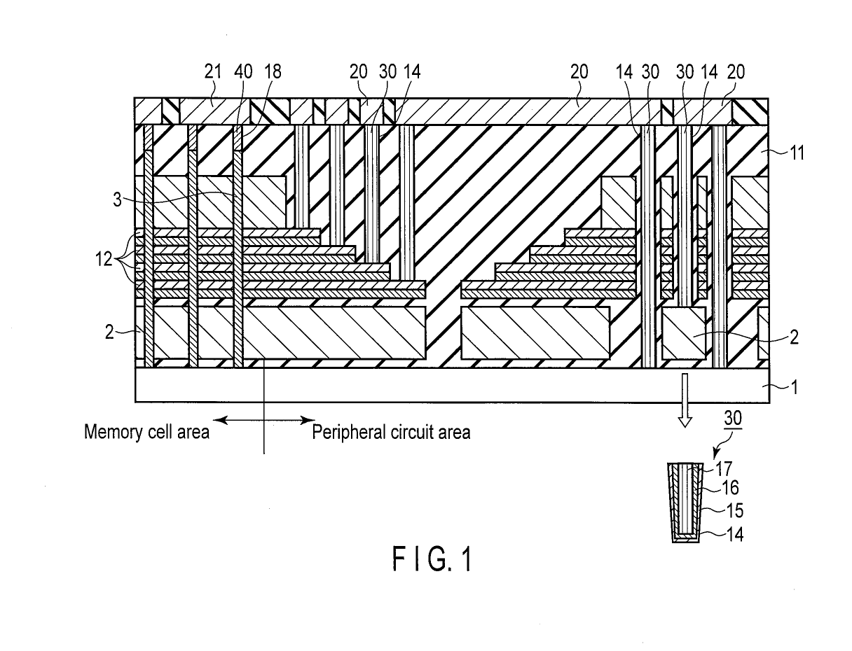

Referring to FIG. 1, a schematic structure of a semiconductor device according to an embodiment is described. The semiconductor device of the embodiment is, for example, a 3D device including a multilayer wiring of an LSI.

As shown in FIG. 1, a plurality of electrodes 2 and a plurality of wirings 12, 20 and 21 are formed on a semiconductor substrate 1 on which semiconductor elements (not shown) such as transistors and capacitors are formed. In a peripheral circuit area, carbon nanotube vias 30 are formed for connecting the wiring 20 and wiring 12, connecting the wiring 20 and the semiconductor elements on the semiconductor substrate 1, and connecting the wiring 20 and electrodes 2. In a memory cell area, metal vias 40 are formed for connecting the wiring 21 and the semiconductor elements on the semiconductor substrate 1 by means of vias 3.

The carbon nanotube via 30 is longer (greater in height) than the metal via 40, and is thicker (greater in diameter) than the metal via 40. Specifically, the carbon nanotube via 30 is formed for a via hole 14 with a large via height and a large diameter, and the metal via 40 is formed for a fine via hole 18 with a small via height.

The carbon nanotube 30 and metal via 40 are formed in the same layer (identical layer, identical level). In other words, the carbon nanotube via 30 and metal via 40 are connected to the wirings 20 and 21 which are formed in the same layer. The wirings 20 and 21 are formed on an upper surface of the same insulation film 11, and are disposed one the same level. The bottom surface of the wiring 20 is on a level with the bottom surface of the wiring 21. The upper surface of the carbon nanotube via 30 is on a level with the upper surface of the metal via 40. The bottom surface of the carbon nanotube via 30 is not on a level with the bottom surface of the metal via 40. The bottom surface of the carbon nanotube via 30 is closer to the semiconductor substrate 1 than the bottom surface of the metal via 40. The carbon nanotube via 30 is, for example, a via which is connected to a control gate or a semiconductor device on the semiconductor substrate 1.

The carbon nanotube via 30 is formed of a catalyst underlayer 15, a catalyst layer 16 and a carbon nanotube 17. The catalyst underlayer 15 is formed on the bottom surface and side surface of the via hole 14, and the catalyst layer 16 is formed on the catalyst underlayer 15 on the bottom surface and side surface of the via hole 14. The carbon nanotube 17 vertically extends (grows) from the catalyst layer 16 on the bottom surface of the via hole 14, and is buried in the via hole 14.

The catalyst underlayer 15 is an auxiliary film for facilitating formation of the carbon nanotube 17. The catalyst underlayer 15 promotes uniform growth of the carbon nanotube 17, and prevents diffusion of a catalyst into a nearby insulation film or an underlayer contact. Examples of the material of the catalyst underlayer 15 include Ta, Ti, Ru, W, Al, nitrides and oxides thereof, and a multilayer material including such materials.

The catalyst layer 16 is a layer which is necessary for growing the carbon nanotube 17. Examples of the material of the catalyst layer 16 include elemental metals such as Co, Ni, Fe, Ru and Cu, an alloy including at least any one of these elemental metals, and carbides of such materials. It is desirable that the catalyst layer 16 be a discontinuous film in a dispersed state. Thereby, the carbon nanotube 17 with a high density can be grown in the via hole 14. When the catalyst layer 16 is formed as a discontinuous film, it is desirable that the film thickness of the catalyst layer 16 be less than, for example, 5 nm.

The carbon nanotube 17 becomes an electrical conduction layer. In order to fix the carbon nanotube 17, an insulation film or metal, which is formed by, e.g. CVD, may be buried in the carbon nanotube 17.

Examples of the material of the metal via 40 include W, Cu, Ni, and Al.

The wiring 21 may be separately formed of a metal film different from a metal film which constitutes the metal via 40. The wirings 20 and 21 may be formed of the same metal film as the metal film which constitutes the metal via 40.

In the meantime, a diffusion barrier (not shown) may be formed in a manner to cover the wiring structure. For example, SiN is used for the diffusion barrier.

In addition, the area where the carbon nanotube via 30 is formed is not limited to the peripheral circuit area, and the area where the metal via 40 is formed is not limited to the memory cell area. The area where each of the carbon nanotube via 30 and metal via 40 is formed may be any one of the memory cell area, peripheral circuit area and select gate area, or the carbon nanotube via 30 and metal via 40 may be mixedly present in the same area among these areas.

[2-1] Height of Via

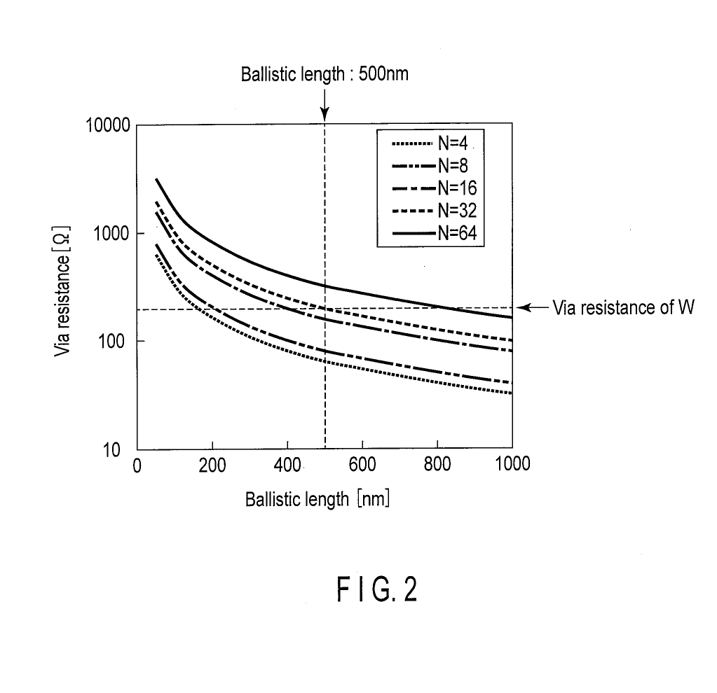

Referring to FIG. 2, a description is given of the height of the carbon nanotube via 30 which is used in the semiconductor device of the present embodiment.

The present embodiment relates to a low-resistance wiring structure which makes use of the fact that the resistance of the carbon nanotube is lower than that of the metal in long-distance wiring, and the resistance of the metal is lower than that of the carbon nanotube in short-distance wiring.

In this case, the border line between the long-distance wiring and short-distance wiring is determined by the ballistic length of the carbon nanotube.

FIG. 2 shows provisional calculations of the ballistic length dependency of the via resistance. In FIG. 2, cases in which the numbers N of layers of multilayer carbon nanotubes are 4, 8, 16, 32 and 64 are taken as examples. FIG. 2 shows the carbon nanotube via resistance when the via diameter is 80 nm, height h is 2400 nm and aspect ratio (A/R) is 30, on the assumption that carbon nanotubes are filled with a maximum density. In addition, W (tungsten), which is usually used as via material, is shown as an object of comparison.

As shown in FIG. 2, the carbon nanotube with any one of the numbers N of layers has a via resistance which becomes lower as the ballistic length increases. On the other hand, the via resistance of W is constant (about 300Ω), without depending on the length.

From this relationship, it is understood that when the ballistic length is 500 nm or more, the via resistance of the carbon nanotubes with about 16 to 32 layers, which are considered to be capable of being stably independent even over large length, becomes lower than the via resistance of W. Thus, based on the ballistic length dependency of the via resistance of the carbon nanotube, it is effective to form a carbon nanotube via for a via with a height of 500 nm or more. On the other hand, as regards a via with a height of less than 500 nm (e.g. via diameter=80 nm, A/R=6), the via resistance of the carbon nanotube is constant (e.g. 6450Ω/number of nanotubes·number of layers), and the resistance of the W via becomes lower.

As has been described above, when the carbon nanotube with the ballistic length of 500 nm is used, the carbon nanotube can make the resistance lower than the conventional metal material as regards the via with the via height of 500 nm or more. However, when the via height is less than 500 nm, the resistance becomes constant since there is no scattering of electrons in the carbon nanotube. Thus, in the case of the carbon nanotube, compared to the metal via, it becomes difficult to reduce the resistance as the via height becomes smaller. Therefore, as regards the via height of less than 500 nm, the conventional metal material is more effective than the carbon nanotube in reducing the resistance.

Thus, in the present embodiment, it is advantageous to use the metal via 40 for the via with the via height of less than 500 nm, and to use the carbon nanotube via 30 for the via with the via height of 500 nm or more.

[2-2] Diameter of Via

In the case of the carbon nanotube via 30, it is difficult to apply carbon nanotubes to a fine via, since the catalyst layer 16 and underlayer 15 are formed on the via side wall and the diameter of the carbon nanotube having metallic electrical characteristics is 20 nm or more.

For example, when the total film thickness of the catalyst layer 16 and underlayer 15 on the via side wall is 20 nm, a desired carbon nanotube 17 cannot be formed for the via with the diameter of 60 nm or less.

Thus, in the present embodiment, it is advantageous to use the metal via for the via with the via diameter of less than 60 nm, and to use the carbon nanotube via 30 for the via with the via diameter of 60 nm or more.

[3] Manufacturing Method

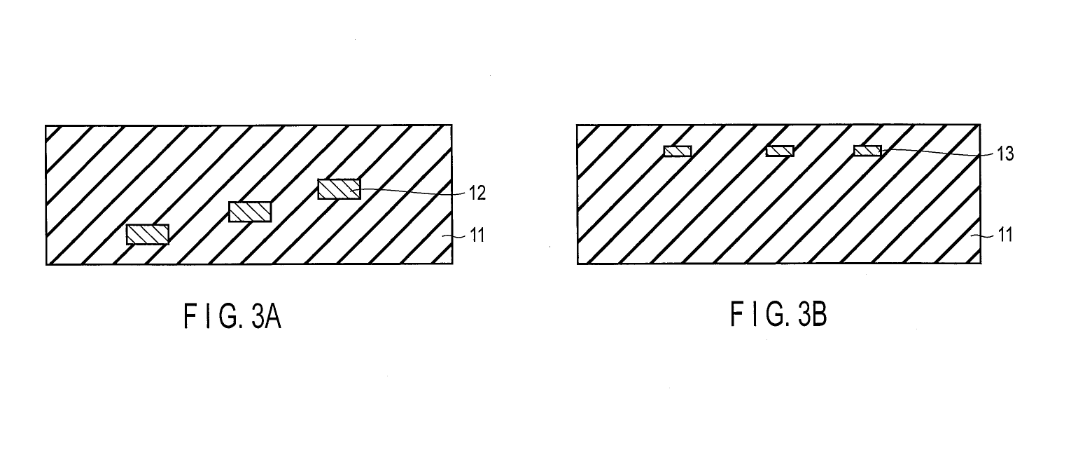

Referring to FIGS. 3A and 3B through FIGS. 11A and 11B, a manufacturing method of a semiconductor device according to an embodiment is described. Each Figure with “A” shows, for example, a peripheral circuit area, and each Figure with “B” shows, for example, a memory cell area.

To begin with, as shown in FIG. 3A and FIG. 3B, an insulation film 11 is formed on a semiconductor substrate (not shown) on which semiconductor elements (not shown), such as transistors and capacitors, are formed. Wirings 12 and 13, which are connected to the semiconductor elements, are formed in the insulation film 11. For example, a TEOS (Tetra Ethyl Ortho Silicate) film is used for the insulation film 11, and an elemental metal, such as W, Cu, or Al, is used for the conductive material of the wirings 12 and 13. The wiring 12 and wiring 13 are different with respect to thickness, width, and layers in which these wirings are formed. For example, the wiring 12 is thicker and wider than the wiring 13, and are formed at deeper locations near the substrate.

An insulation film 11 for forming vias of upper-layer wiring are formed on the wirings 12 and 13 and insulation film 11. This insulation film 11 is formed of, e.g. an SiOC film. The insulation film 11 is formed by, for example, a CVD method or a coating method. This insulation film 11 may be a film including pores in order to lower the dielectric constant.

Subsequently, a cap film (not shown) is formed as a protection film against RIE (Reactive Ion Etching) damage and CMP (Chemical Mechanical Polish) damage of the insulation film 11. The cap film is, for example, an SiO₂ or SiOC film. The cap film may not particularly be formed in the case where the insulation film 11 is a film (e.g. TEOS film) which is robust to RIE damage, or an SiOC film including no pores. The process up to this is the same as in a conventional wiring formation method.

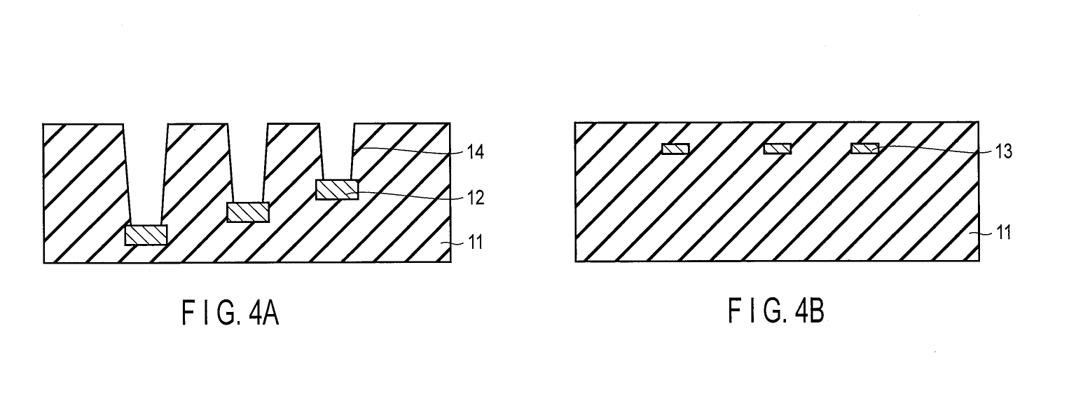

Next, as shown in FIG. 4A, a resist (not shown) is coated on the cap film, the resist is subjected to a lithography step, and the resist is patterned. Using the patterned resist as a mask, the insulation film 11 is processed by RIE. Thereby, via holes 14, which expose the surface of the wiring 12, are formed in the insulation film 11. In the meantime, at this time, as shown in FIG. 4B, via holes, which expose the surface of the wiring 13, are not formed.

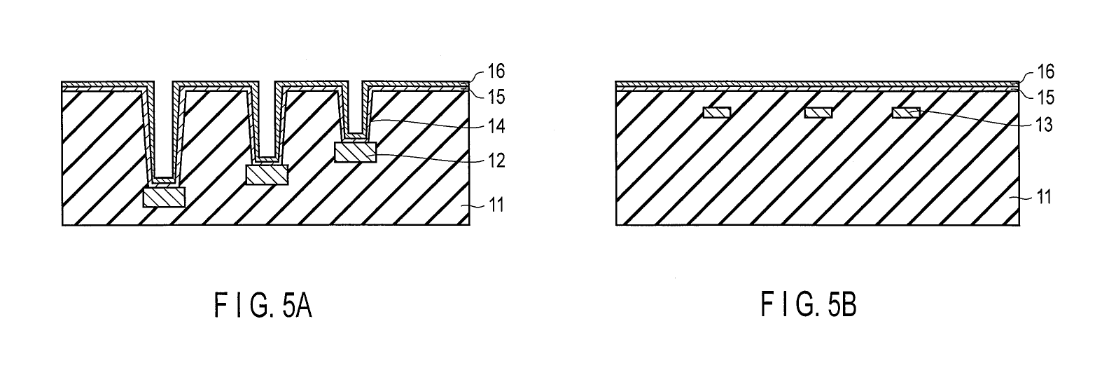

Subsequently, as shown in FIG. 5A and FIG. 5B, by using, for example, a CVD method, an underlayer 15 of a catalyst is formed on the exposed surface of the wiring 12 at the bottom surfaces of the via holes 14, on the insulation film 11 at the side surfaces of the via holes 14, and on the upper surface of the insulation film 11. A catalyst layer 16 is formed on the underlayer 15.

In this case, the underlayer 15 becomes an auxiliary film for facilitating fabrication of carbon nanotubes 17. It is desirable that a part of the underlayer 15 at the bottom surface of the via hole 14 and a part of the underlayer 15 on the insulation film 11 be formed to have a uniform film thickness. The catalyst layer 16 is used for growing the carbon nanotubes 17. It is desirable that the catalyst layer 16 be a discontinuous film in a dispersed state, thereby to grow carbon nanotubes 17 with a high density.

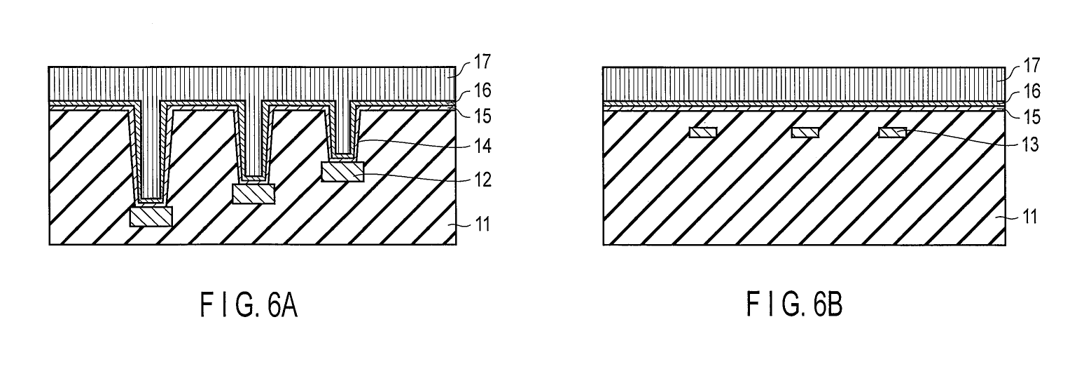

Next, as shown in FIG. 6A and FIG. 6B, carbon nanotubes 17, which become an electrically conductive layer, are grown from the catalyst layer 16 at the bottom surfaces of the via holes 14, and from the catalyst layer 16 on the upper surface of the insulation film 11. For example, CVD is used to form the carbon nanotubes 17. A hydrocarbon gas, such as methane or acetylene, or a mixture gas thereof, is used as the carbon source of the CVD, and hydrogen or inert gas is used as a carrier gas. For example, the upper limit of the process temperature is about 1000° C., the lower limit is about 200° C., and the temperature for growth should preferably be about 350° C. It is effective to use a remote plasma, and to dispose an electrode (not shown) on the substrate and apply a voltage, thereby to remove irons and electrons. In this case, the application voltage should preferably be about 0 V to ±100 V. Thereafter, an SiO₂ film of SOD (Spin on Direct: coating film) is impregnated in the carbon nanotubes 17, and the carbon nanotubes 17 are fixed.

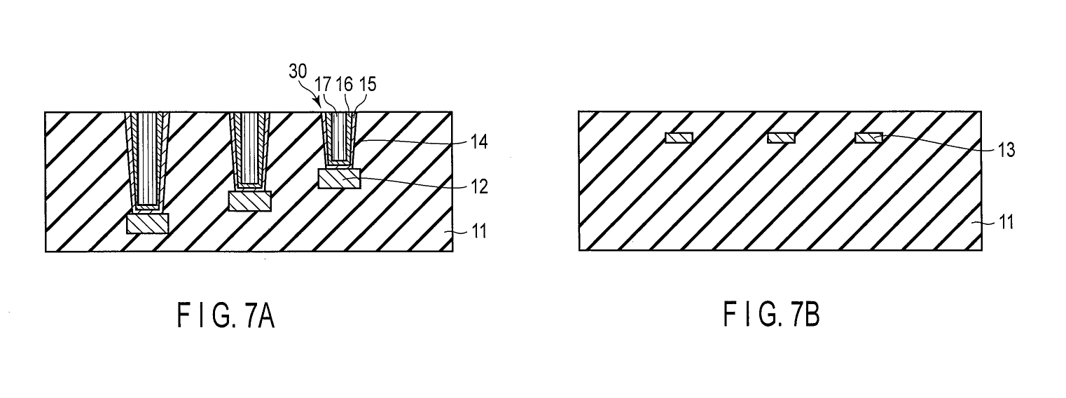

Subsequently, as shown in FIG. 7A and FIG. 7B, the carbon nanotubes 17, catalyst layer 16 and underlayer 15, which are formed as excess portions on the upper surface of the insulation film 11, are removed by, e.g. CMP. At this time, in order to reduce the dielectric constant, the cap insulation film may also be removed. In this manner, carbon nanotubes 30 are formed in the insulation film 11.

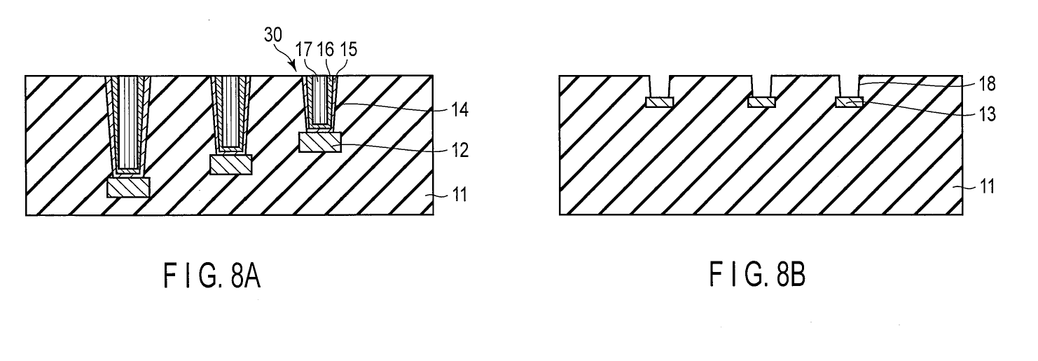

Next, as shown in FIG. 8B, a resist (not shown) is coated on the insulation film 11, the resist is subjected to a lithography step, and the resist is patterned. Using the patterned resist as a mask, the insulation film 11 is processed by RIE. Thereby, via holes 18, which expose the surface of the wiring 13, are formed in the insulation film 11. In the meantime, at this time, the area of FIG. 8A is covered with the resist.

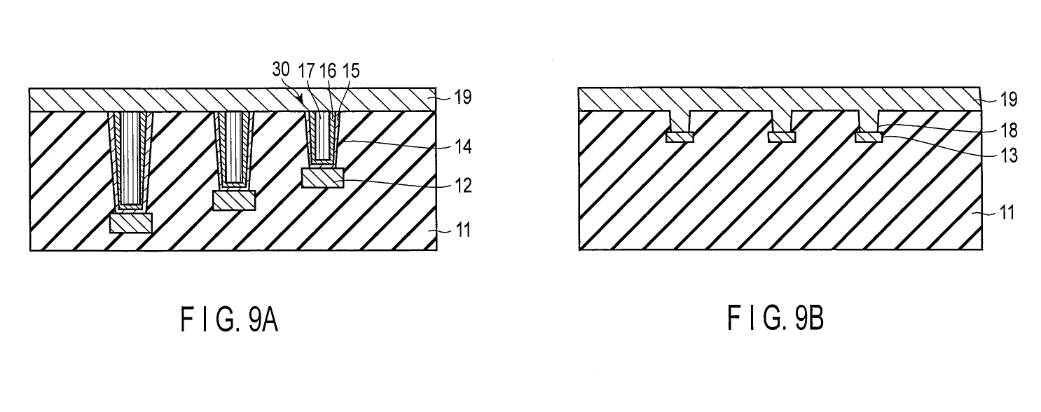

Subsequently, as shown in FIG. 9A and FIG. 9B, a metal film 19 is formed on the insulation film 11, and the via holes 18 are filled with the metal film 19. Examples of the material of the metal film 19 are W, Al, and Cu. In this case, a barrier metal layer (not shown) may be formed under the metal film 19. The barrier metal layer is formed by, for example, PVD (Physical Vapor Deposition), CVD, or an atomic layer vapor phase growth method. Examples of the material of the barrier metal layer include Ta, Ti, Ru, Co, Mn, and nitrides and oxides of these elements.

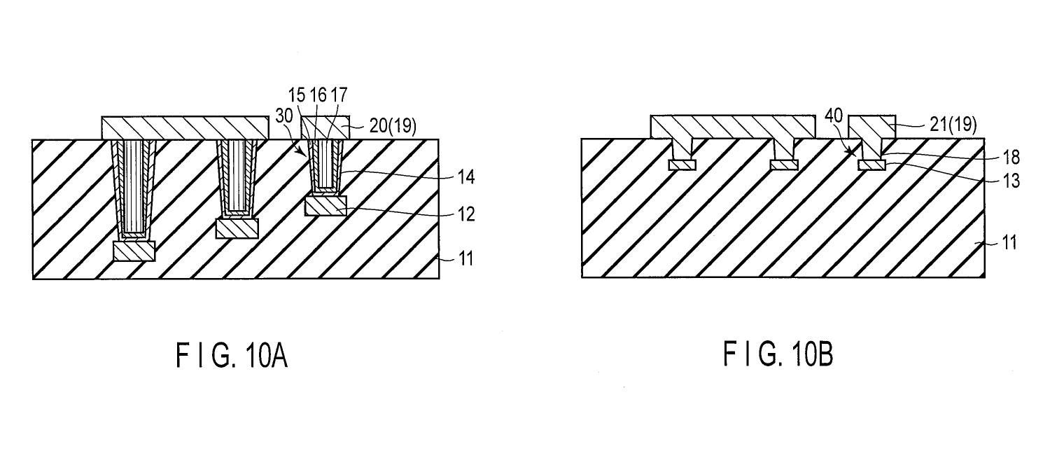

Then, as shown in FIG. 10A and FIG. 10B, a resist (not shown) is coated on the metal film 19, the resist is subjected to a lithography step, and the metal film 19 is processed by RIE. Thereby, a wiring 20 which is connected to the carbon nanotube via 30, a metal via 40 which is connected to the wiring 13, and a wiring 21 which is connected to the metal via 40 are formed.

In the meantime, the formation of the wirings 20 and 21 is not limited to the case in which the wirings 20 and 21 are formed of the same metal film 19 as the metal via 40 at the same time as the metal via 40. For example, after the metal film 19 is formed on the insulation film 11, the metal film 19 on the insulation film 11 is removed by CMP, and the metal via 40 is formed. Thereafter, a metal film is newly formed on the carbon nanotube via 30 and metal via 40, and this metal film is processed by RIE. Thereby, the wirings 20 and 21 may be formed.

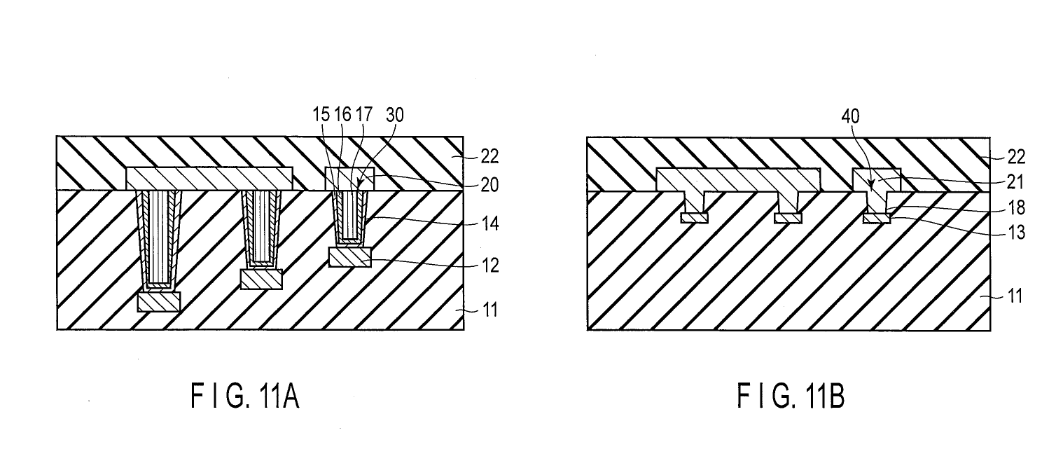

At last, as shown in FIG. 11A and FIG. 11B, an insulation film 22 is formed on the wirings 20 and 21 and the insulation film 11, and an upper layer (not shown) is formed.

[4] Advantageous Effects

In the present embodiment, in a semiconductor device such as a 3D device in which contact vias with a plurality of heights and diameters are present in the same layer, the carbon nanotube via 30 is used for a via with a large height and a large diameter, and the metal via 40 is used for a fine contact with a small height. Thereby, a structure, in which the carbon nanotube via 30 and the metal via 40 are mixedly present in the same layer, is formed. Thus, in the via hole 14 with a large height and a large diameter, the carbon nanotube via 30 is formed, thereby realizing a low resistance in the via with a large height and a large diameter. In the fine via hole 18 with a small height, the metal via 40 is formed, whereby an increase in resistance of the fine via with a small height can be avoided. Therefore, in the semiconductor device in which vias with plural heights and diameters are mixedly present in the same layer, compared to the case in which all vias are formed of metal vias or carbon nanotube vias, it is possible to reduce both the resistance of the via with the large height and large diameter and the resistance of the fine via with the small height.

In addition, in the case of the carbon nanotube via 30, in the fabrication process, the via hole 14 is filled with the carbon nanotube 17, and the upper-layer wiring 20 is separately formed. In this case, in the present embodiment, by using the metal film 19 which is used for forming the metal via 40 and upper-layer wiring 21, the upper-layer wiring 20 of the carbon nanotube via 30 can be formed at the same time as the metal via 40 and upper-layer wiring 21. Therefore, according to the manufacturing method of the present embodiment, the formation of the upper-layer wiring 20 of the carbon nanotube 30 can be made coexistent with the batchwise process of filling the via hole 18 with the metal via 40 and forming the upper-layer wiring 21.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first wiring;
a second wiring disposed in the same layer as the first wiring;
a first via connected to a bottom surface of the first wiring and formed of a carbon nanotube; and
a second via connected to a bottom surface of the second wiring and formed of a metal.

2. The device according to claim 1, wherein the first via is longer than the second via.

3. The device according to claim 1, wherein a length of the first via is 500 nm or more, and a length of the second via is less than 500 nm.

4. The device according to claim 1, wherein the first via is thicker than the second via.

5. The device according to claim 1, wherein a diameter of the first via is 60 nm or more, and a diameter of the second via is less than 60 nm.

6. The device according to claim 1, wherein an upper surface of the first via is on a level with an upper surface of the second via.

7. The device according to claim 1, wherein a bottom surface of the first via is closer to a semiconductor substrate than a bottom surface of the second via.

8. The device according to claim 1, wherein the first wiring and the second wiring are formed of the metal.

9. The device according to claim 1, wherein the first via is formed in a peripheral circuit area, and the second via is formed in a memory cell area.

10. The device according to claim 1, wherein the first via comprises:
an underlayer formed on a bottom surface and a side surface of a via hole;
a catalyst layer formed on the underlayer on the bottom surface and the side surface of the via hole; and
the carbon nanotube grown from the catalyst layer and buried in the via hole.

11. The device according to claim 10, wherein the catalyst layer is a discontinuous film in a dispersed state.

12. A method of manufacturing a semiconductor device, comprising:
forming an insulation film including a first area and a second area;
forming a first via hole in the insulation film of the first area;
forming a first via of a carbon nanotube in the first via hole;
forming a second via hole in the insulation film of the second area; and
forming a second via of a metal in the second via hole.

13. The method according to claim 12, further comprising:
forming, after the forming of the second via hole, a metal film of the metal on the insulation film of the first area and the second area, on the first via, and in the second via hole;
forming a first wiring which is connected to the first via, by processing the metal film;
forming the second via in the second via hole; and
forming a second wiring which is connected to the second via.

14. The method according to claim 12, wherein the second via hole is formed after the first via is formed.

15. The method according to claim 12, wherein the first via is longer than the second via.

16. The method according to claim 12, wherein a length of the first via is 500 nm or more, and a length of the second via is less than 500 nm.

17. The method according to claim 12, wherein the first via is thicker than the second via.

18. The method according to claim 12, wherein a diameter of the first via is 60 nm or more, and a diameter of the second via is less than 60 nm.

19. The method according to claim 12, wherein an upper surface of the first via is on a level with an upper surface of the second via.

20. The method according to claim 12, wherein a bottom surface of the first via is closer to a semiconductor substrate than a bottom surface of the second via.
